(19) United States
(12) Patent Application Publication
(10) Pub. No.: US 2026/0136492 A1
(43) Pub. Date: May 14, 2026

(54) FASTENING STRUCTURE FOR HEAT DISSIPATOR, SHIELDING CAGE ASSEMBLY, AND OPTICAL MODULE APPARATUS

(71) Applicant: Luxshare Thermal Technologies (HuiZhou) Co.,Ltd, Huizhou City (CN)

(72) Inventors: Tao Sun, Huizhou City (CN); Bok Zeng, Huizhou City (CN); Jun Zhao, Huizhou City (CN); Pengfei Wang, Huizhou City (CN)

(73) Assignee: Luxshare Thermal Technologies (HuiZhou) Co.,Ltd, Huizhou City (CN)

(21) Appl. No.: 19/387,372

(22) Filed: Nov. 12, 2025

(30) Foreign Application Priority Data
Nov. 12, 2024 (CN) 202411613670.0

(51) Int. Cl. H05K 7/20; G02B 6/42; H05K 9/00

(52) U.S. Cl. CPC H05K 7/20263; G02B 6/4269; G02B 6/4278; H05K 7/20254; H05K 9/0058

(57) ABSTRACT

Provided are a fastening structure for a heat dissipator, a shielding cage assembly, and an optical module apparatus. The fastening structure includes a first fastening member and a second fastening member. Corresponding side surfaces of the first fastening member and the second fastening member are connected in a snap-fitting manner. An accommodating space for placing the heat dissipator is formed after the first fastening member and the second fastening member are buckled. Snap parts for connecting with a shielding cage in a snap-fitting manner are arranged on side surfaces of the first fastening member. Elastic pressing sheets for pressing the heat dissipator are arranged on the top surface of the first fastening member.

### CROSS-REFERENCE TO RELATED APPLICATION

This application claims the benefit of Chinese Patent Application No. 202411613670.0, filed on November 12, 2024, entitled “Fastening structure for a heat dissipator, Shielding cage assembly, and Optical module apparatus”, which is incorporated herein by reference in its entirety.

### TECHNICAL FIELD

The present disclosure relates to the technical field of communication devices, and specifically relates to a fastening structure for a heat dissipator, a shielding cage assembly, and an optical module apparatus.

### BACKGROUND

At present, the outer sides of an optical module are fixed through a shielding cage, and a heat dissipator is arranged above the shielding cage to realize heat dissipation for the optical module. The heat dissipator is generally connected with the shielding cage through a fastening structure. The heat dissipator is limited and fixed in an accommodating space formed between the fastening structure and the shielding cage, so that fixation between the heat dissipator and the optical module is realized. The existing fastening structure for the heat dissipator is a semi-closed clamping-connection structure, and the heat dissipator is prone to displacement or loosening when external impact or vibration occurs.

### SUMMARY

Embodiments of the present disclosure provide a fastening structure for a heat dissipator, a shielding cage assembly, and an optical module apparatus.

In one aspect, embodiments of the present disclosure provide a fastening structure for a heat dissipator, and the fastening structure includes: a first fastening member and a second fastening member.

The first fastening member includes a first rectangular box structure. The first rectangular box structure includes an opening at a bottom. Each of four side surfaces of the first fastening member includes a first snap part, each of the two side surfaces of the first fastening member includes a second snap part, and a top surface of the first fastening member includes a plurality of elastic pressing sheets.

The second fastening member includes a second rectangular box structure. The second rectangular box structure includes an opening at a top. Each of four side surfaces of the second fastening member includes a first snap-fitting part.

When the first fastening member and the second fastening member are fastened in an up-down direction, the first snap parts of the first fastening member and the first snap-fitting parts of the second fastening member are engaged in one-to-one correspondence. An accommodating space for placing the heat dissipator is formed between the first fastening member and the second fastening member. The second snap parts are configured to be connected to a shielding cage in a snap-fitting manner, and the elastic pressing sheets extend towards an interior of the accommodating space, and are configured to press the heat dissipator.

In another aspect, embodiments of the present disclosure provide a shielding cage assembly, and the shielding cage assembly includes: the fastening structure described in the above aspect, a shielding cage, and a heat dissipator. Two sides of the shielding cage are provided with second snap-fitting parts which are configured to be engaged with the second snap parts of the fastening structure in a snap-fitting manner. The fastening structure is disposed above and fastened to the shielding cage in a snap-fitting manner. The heat dissipator is arranged in the accommodating space of the fastening structure.

In yet another aspect, embodiments of the present disclosure provide an optical module apparatus, and the optical module apparatus includes: the shielding cage assembly described in the above aspect; and optical modules arranged in the shielding cage.

### BRIEF DESCRIPTION OF DRAWINGS

The above and other objectives, features, and advantages of the present disclosure will become clearer through the following descriptions for the examples of the present disclosure with reference to the drawings, and in the drawings:

FIG. 1 is a schematic exploded diagram of a fastening structure for a heat dissipator according to an embodiment of the present disclosure;

FIG. 2 is a schematic structure diagram of a first fastening member according to an embodiment of the present disclosure;

FIG. 3 is a schematic structure diagram of the fastening structure according to an embodiment of the present disclosure;

FIG. 4 is a schematic structure diagram showing a heat dissipator installed in the fastening structure according to an embodiment of the present disclosure;

FIG. 5 is a schematic structure diagram showing the heat dissipator installed in the fastening structure from another angle according to an embodiment of the present disclosure;

FIG. 6 is a schematic structure diagram of the heat dissipator according to an embodiment of the present disclosure;

FIG. 7 is a schematic structure diagram of the heat dissipator from another angle according to an embodiment of the present disclosure;

FIG. 8 is a schematic exploded diagram of the heat dissipator according to an embodiment of the present disclosure;

FIG. 9 is a schematic structure diagram of a shielding cage according to an embodiment of the present disclosure;

FIG. 10 is a schematic structure diagram of an optical module apparatus according to an embodiment of the present disclosure; and

FIG. 11 is a schematic exploded diagram of the optical module apparatus according to an embodiment of the present disclosure.

### DETAILED DESCRIPTION OF THE EMBODIMENTS

The present disclosure is described below on the basis of the embodiments, but is not merely limited to these embodiments. Specific details are described in detail in the following detailed description of the present disclosure. The present disclosure can also be fully understood by a person skilled in the art without the description of the details. In order to avoid confusing the essence of the present disclosure, commonly known method, process, flow, element and circuit are not described in detail.

In addition, a person skilled in the art should understand that the drawings herein are provided for the purpose of description only, and are not necessarily drawn in proportion.

Unless otherwise specified and limited, the terms "installed", "connected", "connection", "fixed", and the like should be understood in a broad sense, such as fixed connection, detachable connection, integration, mechanical connection, electric connection, direct connection, indirect connection through an intermediate medium, internal communication of two elements, or an interaction relationship between two elements, unless otherwise specified. Those of ordinary skill in the art may understand the specific meanings of the above terms in the present disclosure according to specific circumstances.

Unless explicitly required by the context, the words such as "including" and "containing" in the entire application document should be interpreted as containing meaning rather than exclusive or exhaustive meaning; that is to say, the words mean "including but not limited to". In the descriptions of the present disclosure, it needs to be understood that, the terms "first", "second", etc. are merely used for a purpose of description, and cannot be understood as indicating or implying relative importance. In addition, in the descriptions of the present disclosure, unless otherwise stated, "a plurality of" means two or more.

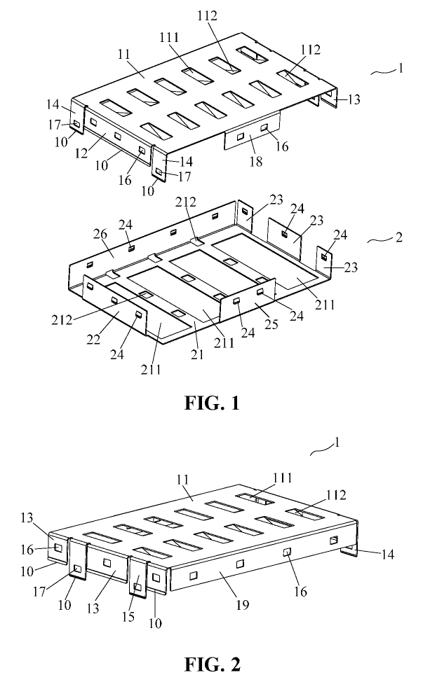

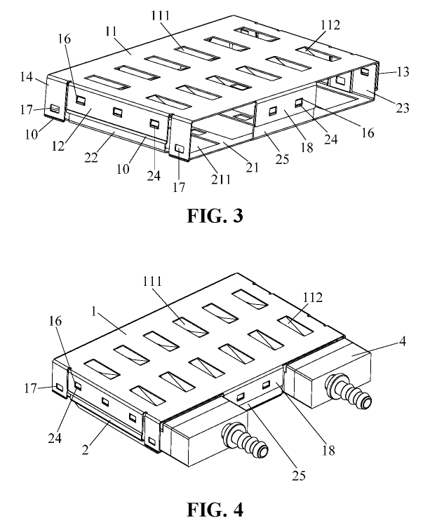

FIG. 1 to FIG. 3 are schematic diagrams of a fastening structure for a heat dissipator according to embodiments of the present disclosure. As shown in FIG. 1 to FIG. 3, a fastening structure for a heat dissipator includes a first fastening member 1 and a second fastening member 2. The first fastening member 1 and the second fastening member 2 are fastened by snap-fitting of their side plates. The first fastening member 1 and the second fastening member 2 form an accommodating space for placing a heat dissipator 4. According to the fastening structure of the embodiments, the first fastening member 1 and the second fastening member 2 are connected in an up-down direction to wraps the heat dissipator 4, thereby providing better mechanical support. The heat dissipator 4 is prevented from displacement or loosening when external impact or vibration occurs, so that stability and reliability of the heat dissipator 4 are ensured. Meanwhile, the fastening structure covers all sides of the heat dissipator, the heat dissipator and the fastening structure as a whole are moved and adjusted according to different heat dissipation needs, which is applicable to many different devices and application scenes.

The first fastening member 1 is of a first rectangular box structure with an opening at its bottom. Each of four side surfaces of the first fastening member 1 includes a first snap part 16. The second fastening member 2 is of a second rectangular box structure with an opening at its top. Each of four side surfaces of the second fastening member 2 includes a first snap-fitting parts 24. When the first fastening member 1 and the second fastening member 2 are connected in a snap-fitting manner in an up-down direction, the first snap parts 16 of the first fastening member 1 and the first snap-fitting parts 24 of the second fastening member 2 are engaged in one-to-one correspondence, and an accommodating space for placing the heat dissipator 4 is formed between the first fastening member 1 and the second fastening member 2. The fastening structure is assembled through the above snap-fitting fastening manner, and may be assembled or detached without tools, so that maintenance and replacement are facilitated. The four side surfaces of the first fastening member 1 include two side surfaces arranged along a length direction of the first fastening member 1. Each of the two side surfaces arranged along a length direction is further provided with a second snap part 17. The second snap part 17 is configured to be connected to a shielding cage 3 in a snap-fitting manner. Therefore, installation and detachment for the fastening structure and the shielding cage 3 are facilitated, and simpler installation is achieved.

In some embodiments, as shown in FIG. 1 and FIG. 2, the first fastening member 1 includes a top plate 11, a first upper side plate 12, a second upper side plate 13, a third upper side plate 14, and a fourth upper side plate 15. The first upper side plate 12 and the third upper side plate 14 are located at one side (i.e., the same side) in a length direction of the top plate 11, and the second upper side plate 13 and the fourth upper side plate 15 are located at the other side (i.e., the same other side) in the length direction of the top plate 11. The first upper side plate 12 and the third upper side plate 14 are positioned at one side of the top plate 11 and arranged in a width direction, and the second upper side plate 13 and the fourth upper side plate 15 are positioned at the other side of the top plate 11 and arranged in the width direction. The first upper side plate 12, the second upper side plate 13, the third upper side plate 14, and the fourth upper side plate 15 are vertically connected to the top plate 11, and collectively form a rectangular box structure with an opening at the bottom.

As shown in FIG. 1, the second fastening member 2 includes a bottom plate 21, a first lower side plate 22, and a second lower side plate 23. The first lower side plate 22 and the second lower side plate 23 are located at two sides of the bottom plate 21 in a length direction. The first lower side plate 22 and the second lower side plate 23 are vertically connected to the bottom plate 21, and collectively form a rectangular box structure with an opening at the top. The rectangular box structure formed by the second fastening member 2 and the rectangular box structure formed by the first fastening member 1 are basically consistent in size.

As shown in FIG. 1 and FIG. 2, first snap parts 16 are arranged on the first upper side plate 12 and the second upper side plate 13. As shown in FIG. 1, first snap-fitting parts 24 are arranged on the first lower side plate 22 and the second lower side plate 23. The first fastening member 1 and the second fastening member 2 are connected through snap-fitting between the first snap parts 16 and the first snap-fitting parts 24. There are a plurality of the first snap parts 16 and a plurality of the first snap-fitting parts 24 respectively, and a specific number of the first snap parts 16 and a specific number of the first snap-fitting parts 24 are set according to actual needs, so that facilitation for firm installation and facilitation for detachment are achieved. In order to facilitate installation and detachment, the plurality of first snap parts 16 are arranged at intervals in the length direction, and the plurality of first snap-fitting parts 24 are arranged at intervals in the length direction, so that connection stability is improved.

The first upper side plate 12 and the first lower side plate 22 are the same in position in the width direction, the second upper side plate 13 and the second lower side plate 23 are the same in position in the width direction, and the first snap parts 16 and the first snap-fitting parts 24 are the same in number and arranged in one-to-one correspondence in position. When the first fastening member 1 and the second fastening member 2 are connected, the top plate 11 is located above the bottom plate 21, and the first upper side plate 12 and the first lower side plate 22, and the second upper side plate 13 and the second lower side plate 23 are respectively connected together in a snap-fitting manner and through the corresponding first snap parts 16 and first snap-fitting parts 24, so that an accommodating space for placing the heat dissipator 4 is formed.

In some embodiments, the first snap parts 16 are snaping holes, and the snaping holes may be triangular, rectangular, polygonal, or circular. The first snap-fitting parts 24 are bumps protruding towards outer side directions of the corresponding side plates, and the bumps may be triangular, rectangular, polygonal, or circular. The first snap-fitting parts 24 and the first snap parts 16 are connected in a snap manner, and the first snap-fitting parts 24 are located in the snaping holes of the first snap parts 16. When the first fastening member 1 and the second fastening member 2 are connected, the first upper side plate 12 is located at the outer side of the first lower side plate 22, and the second upper side plate 13 is located at the outer side of the second lower side plate 23, therefore, connection stability may be improved, and the first snap-fitting parts 24 and the first snap parts 16 are prevented from being disconnected.

In another embodiment, the first snap parts 16 may be arranged to be bumps, the first snap-fitting parts 24 may be arranged to be snaping holes, the first upper side plate 12 is located at the inner side of the first lower side plate 22, and the second upper side plate 13 is located at the inner side of the second lower side plate 23.

In yet another embodiment, one of the first snap part 16 and the first snap-fitting part 24 is a snaping hole, and the other one of the first snap part 16 and the first snap-fitting part 24 is hanging lug or hanging hook.

As shown in FIG. 1 and FIG. 2, second snap parts 17 are arranged on the third upper side plate 14 and the fourth upper side plate 15. The second snap parts 17 are used for being connected to a shielding cage 3 in a snap-fitting manner, so as to fix the fastening structure to the shielding cage 3, so that positions of the heat dissipator 4 in the fastening structure and optical modules 5 in the shielding cage 3 are fixed, and good heat dissipation and cooling are realized.

There are a plurality of the second snap parts 17, and a specific number of the second snap parts 17 is set according to actual needs, so that facilitation installation and detachment are achieved. In order to facilitate installation and detachment, the plurality of second snap parts 17 are arranged at intervals in length directions of the side plates, so that connection stability is improved.

In the embodiment, the second snap parts 17 are snaping holes, and the snaping holes may be triangular, rectangular, polygonal, or circular. Correspondingly, bumps or hanging lugs are arranged on the shielding cage 3, and connected to the snaping holes in a matching manner. The bumps may be triangular, rectangular, polygonal, or circular. In another example, the second snap parts 17 may be arranged to be bumps or hanging lugs, and snaping holes are formed in the corresponding shielding cage 3.

It should be noted that, there may be one or more first upper side plates 12, one or more first lower side plates 22, one or more second upper side plates 13, one or more second lower side plates 23, one or more third upper side plates 14, and one or more fourth upper side plates 15, and there may be one or more first snap parts 16, one or more first snap-fitting parts 24, and one or more second snap parts 17 on the side plates. The first upper side plates 12 and the first lower side plates 22 are consistent in number and in one-to-one correspondence in position, and the first snap parts 16 arranged on the first upper side plates 12 and the first snap-fitting parts 24 arranged on the first lower side plates 22 are consistent in number and corresponding in position, so that connection reliability is ensured. The second upper side plates 13 and the second lower side plates 23 are consistent in number and in one-to-one correspondence in position, and the first snap parts 16 arranged on the second upper side plates 13 and the first snap-fitting parts 24 arranged on the second lower side plates 23 are consistent in number and corresponding in position, so that connection reliability is ensured.

When there are a plurality of the third upper side plates 14 and a plurality of the fourth upper side plates 15, the plurality of third upper side plates 14 are arranged at intervals through the first upper side plates 12, and the plurality of fourth upper side plates 15 are arranged at intervals through the second upper side plates 13. That is, the first upper side plate 12 is arranged between two adjacent third upper side plates 14, and the second upper side plate 13 is arranged between two adjacent fourth upper side plates 15, therefore, connection point positions between the fastening structure and the shielding cage 3 are dispersed, and connection stability is improved. There may be a gap between the first upper side plate 12 and the third upper side plate 14, or the first upper side plate 12 and the third upper side plate 14 may be in an integrally-formed structure (i.e. without a gap).

In one embodiment, there is one first upper side plate 12 and one first lower side plates 22, there are three second upper side plates 13 and three second lower side plates 23, and there are two third upper side plates 14 and two fourth upper side plates 15. The two third upper side plates 14 are located at two sides of the first upper side plate 12, and the two fourth upper side plates 15 are arranged alternately with the three second upper side plates 13, and the outer ones are the second upper side plates 13.

In the present disclosure, "a plurality of" means two or more. A length of the third upper side plates 14 and a length of the fourth upper side plates 15 may be set according to actual needs, and may be greater than or equal to a length of the first upper side plate 12 and a length of the second upper side plates 13.

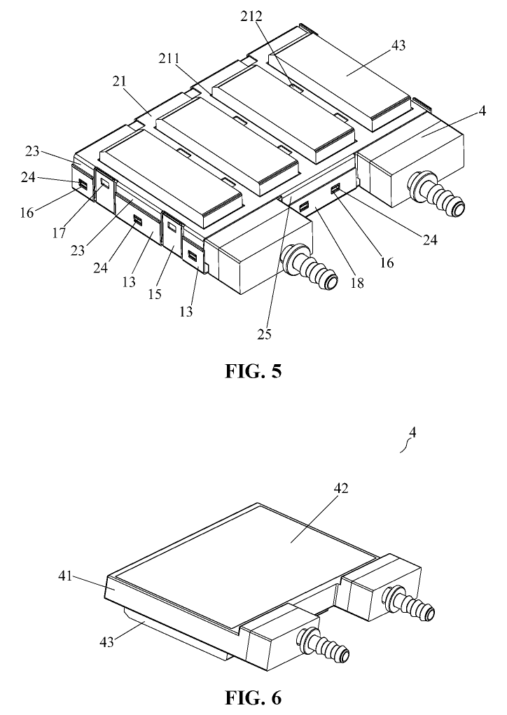

As shown in FIG. 1 and FIG. 2, the first fastening member 1 further includes a fifth upper side plate 18 and a sixth upper side plate 19 which are located at two sides in a width direction of the top plate 11, and the first snap parts 16 are arranged on the fifth upper side plate 18 and the sixth upper side plate 19. As shown in FIG. 1 and FIG. 2, the second fastening member 2 further includes a third lower side plate 25 and a fourth lower side plate 26 which are located at two sides in a width direction of the bottom plate 21, and the first snap-fitting parts 24 are arranged on the third lower side plate 25 and the fourth lower side plate 26. The first snap parts 16 and the first snap-fitting parts 24 have been described above, which will not be further repeated herein. Positions of the fifth upper side plate 18 and the third lower side plate 25 in the length direction are the same, positions of the sixth upper side plate 19 and the fourth lower side plate 26 in the length direction are the same, and the first snap parts 16 and the first snap-fitting parts 24 are the same in number and arranged in one-to-one correspondence in position. As shown in FIG. 4 and FIG. 5, the fifth upper side plate 18 and the third lower side plate 25 are respectively arranged at the middle positions of the top plate 11 and the bottom plate 21, and after the fifth upper side plate 18 and the third lower side plate 25 are connected in the up-down direction, communicating blocks and joints at two sides of the heat dissipator 4 may extend out from the two sides and are connected to a liquid storage apparatus through pipelines.

The first upper side plate 12, the second upper side plates 13, the third upper side plates 14, the fourth upper side plates 15, the fifth upper side plate 18 and the sixth upper side plate 19 are vertically connected to the top plate 11, and collectively form a rectangular box structure with an opening at the bottom. The first lower side plate 22, the second lower side plates 23, the third lower side plate 25, and the fourth lower side plate 26 are vertically connected to the bottom plate 21, and collectively form a rectangular box structure with an opening at the top. The fifth upper side plate 18 and the third lower side plate 25 are connected in a snap-fitting manner through the corresponding first snap parts 16 and first snap-fitting parts 24, and the sixth upper side plate 19 and the fourth lower side plate 26 are connected in a snap-fitting manner through the corresponding first snap parts 16 and first snap-fitting parts 24. The first fastening member 1 and the second fastening member 2 are connected to form an accommodating space which is limited in a left-right direction, an up-down direction and a front-rear direction, and the heat dissipator is arranged in the accommodating space, thereby preventing the heat dissipator from shaking.

As shown in FIG. 1 and FIG. 2, guide plates 10 are arranged on the first upper side plate 12, the second upper side plate 13, the third upper side plate 14, and the fourth upper side plate 15. The guide plate 10 extends in a direction away from the top plate 11, and is inclined away from the corresponding side plate. That is, the guide plate 10 on the first upper side plate 12 is inclined away from the first upper side plate 12, the guide plate 10 on the second upper side plate 13 is inclined away from the second upper side plate 13, the guide plate 10 on the third upper side plate 14 is inclined away from the third upper side plate 14, and the guide plate 10 on the fourth upper side plate 15 is inclined away from the fourth upper side plate 15. With the guide plates 10, fastening the first fastening member 1 on the second fastening member 2 and the shielding cage 3 is facilitated. When the first fastening member 1 and the second fastening member 2 are installed, precise alignment is not needed, and the installation may be rapidly realized through guide assistance of the guide plates 10. When the whole fastening structure and the shielding cage 3 are installed, the installation may be rapidly realized through guide assistance of the guide plates 10. The guide plates 10 may reduce installation difficulty for the fastening structure for the heat dissipator, so that installation efficiency is increased.

A plurality of elastic pressing sheets 112 are arranged on the top surface of the first fastening member 1, and extend towards the inner side of the top surface. After the first fastening member 1 and the second fastening member 2 are connected, the elastic pressing sheets 112 are used for pressing the upper surface of the heat dissipator 4 to prevent the heat dissipator 4 from moving in the accommodating space.

In some embodiments, as shown in FIG. 1 and FIG. 2, first heat dissipation holes 111 are formed in the top plate 11 of the first fastening member 1. The first heat dissipation holes 111 are used for increasing heat exchange efficiency between the heat dissipator 4 located in the accommodating space and outside air, so that cooling efficiency for the heat dissipator 4 is increased. The first heat dissipation holes 111 may be, but not limited to, rectangular holes, and may also be selected to be circular, triangular, or polygonal. In some embodiments, there are a plurality of first heat dissipation holes 111, and the plurality of first heat dissipation holes 111 are respectively formed at intervals in the length direction and the width direction of the top plate 11, that is, are arranged in a form of a matrix. In addition, the first heat dissipation holes 111 may also be taken as weight-lighting holes for reducing a weight of the first fastening member 1.

Further, the elastic pressing sheet 112 is arranged at one side in the first heat dissipation hole 111. The elastic pressing sheet 112 extends towards the interior of the accommodating space, and is used for pressing the upper surface of the heat dissipator 4 to prevent the heat dissipator 4 from moving in the accommodating space. The elastic pressing sheets 112 may adjust a tightness degree between the heat dissipator 4 and heating elements (such as optical modules 5) through pressing the heat dissipator 4, and may ensure that the heat dissipator 4 is adhered to and tightly pressed against the heating elements (such as the optical modules 5).

In some embodiments, the plurality of first heat dissipation holes 111 are formed in the top plate 11 in a form of a matrix, so that the plurality of elastic pressing sheets 112 are also arranged in a form of a matrix. The plurality of elastic pressing sheets 112 are arranged in a form of a matrix, and may apply a balanced pressure to different positions of the upper surface of the heat dissipator 4, so that the heat dissipator 4 may be connected to and tightly pressed against all the optical modules 5, so that high uniformity of heat dissipation for the optical modules 5 is ensured, a cooling effect on a whole optical module system is improved, and influence on precision of the optical module system due to overheating of local (individual optical modules) is avoided. The dissipator is fixed into the fastening structure. Therefore, when a certain optical module 5 is pulled out, floating and heat dissipation influence on the remaining optical modules 5 are weak.

In some embodiments, the elastic pressing sheets 112 and the top plate 11 are of an integrally-formed structure, that is, when the first heat dissipation holes 111 are formed in the top plate 11 through cutting or stamping, the cut or stamped part is not completely removed from the top plate 11 but forms the elastic pressing sheets 112 extending towards one side of the accommodating space. The elastic pressing sheets 112 and the top plate 11 are integrally formed, so that assembly steps may be reduced, connection is carried out without additional welding or fasteners, and meanwhile, strength and stability may further be improved, and a cost is reduced.

As shown FIG. 1, the bottom plate 21 includes second heat dissipation holes 211. As shown FIG. 5, the second heat dissipation holes 211 allow the heat dissipator 4 to at least partially extend out, so that the extending parts of the heat dissipator 4 may realize limited connection with the shielding cage 3. In addition, the second heat dissipation holes 211 may further be used for increasing heat exchange efficiency between the heat dissipator 4 located in the accommodating space and the outside air, so that cooling efficiency for the heat dissipator 4 is increased. The second heat dissipation holes 211 may be, but not limited to, rectangular holes, and may also be selected to be circular, triangular, or polygonal. In some embodiments, there are a plurality of the second heat dissipation holes 211, and the plurality of second heat dissipation holes 211 are formed at intervals in a length direction of the bottom plate 21. A number of the second heat dissipation holes 211 is set according to a number of the extending parts (i.e., protrusions 43) of the heat dissipator 4, and positions and shapes are basically consistent, so that stretching connection is facilitated.

As shown in FIG. 1, avoidance holes 212 are further formed in the bottom plate 21. There are a plurality of avoidance holes 212, and the plurality of avoidance holes 212 are formed at intervals in a width direction of the bottom plate 21. The avoidance holes 212 are used for avoiding protruding structures on the shielding cage 3 when the fastening structure is connected to the shielding cage 3, so that connection stability is improved.

The fastening structure of the embodiments wraps around the heat dissipator through snap-fitting connection between the first fastening member and the second fastening member, and prevents the heat dissipator from displacement or loosening while external impact or vibration occurs, so that stability and reliability of the heat dissipator are ensured.

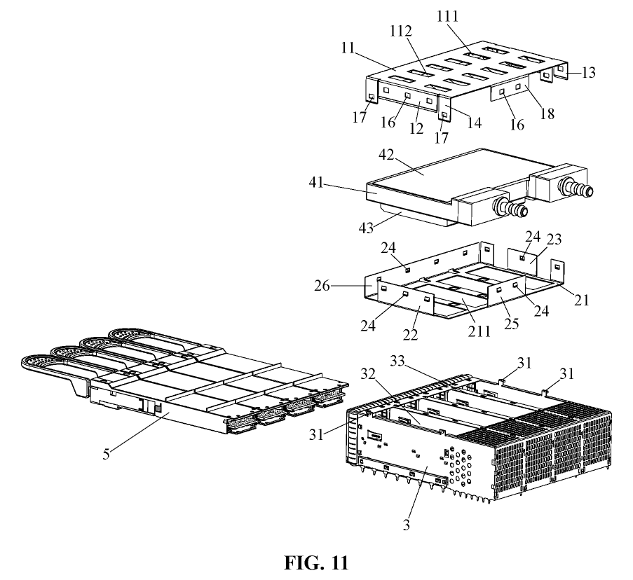

FIG. 10 and FIG. 11 are schematic structure diagrams of optical modules and a shielding cage assembly. The shielding cage assembly includes a fastening structure, a shielding cage 3 and the heat dissipator 4. The fastening structure has been described above and is not repeated herein. As shown in FIG. 4 and FIG. 5, the heat dissipator 4 is installed in the accommodating space of the fastening structure, and is prevented from shaking up, down, left, and right. The heat dissipator 4 and the fastening structure as a whole is assembled and connected to the shielding cage 3, and rapid adjustment for the heat dissipator 4 according to different heat dissipation needs is facilitated, so that assembly and detachment efficiency is increased.

The heat dissipator 4 is, but not limited to, a liquid-cooling heat dissipator, and the liquid-cooling heat dissipator cools optical modules 5 in the shielding cage 3 through introducing a cooling liquid into the heat dissipator 4, so that a better cooling effect is achieved.

As shown in FIG. 6 to FIG. 8, the heat dissipator 4 includes a liquid-cooling plate 41 and a pressing flat plate 42. The pressing flat plate 42 is installed on the top surface of the liquid-cooling plate 41, and is configured to cause the plurality of elastic pressing sheets 112 to abut against the same plane, thereby ensuring the same tightness degree. The pressing flat plate 42 is used for abutting against the elastic pressing sheets 112 of the fastening structure to ensure that the heat dissipator 4 is in contact with and tightly pressed against the optical modules 5 or ensure that the heat dissipator 4 keeps a close distance with the optical modules 5, so as to prevent the heat dissipator 4 from moving up and down. Meanwhile, the plurality of elastic pressing sheets 112 realize tight pressing against the heat dissipator 4 through being abutted against the pressing flat plate 42, thereby ensuring a consistent contact tightness degree or a consistent distance between the heat dissipator 4 and the plurality of optical modules 5, so that uniform heat dissipation for the plurality of optical modules 5 is achieved, and adverse influence due to local overheating is avoided. The liquid-cooling plate 41 includes an internal flow channel, the internal flow channel includes a liquid outlet port and a liquid inlet port, the liquid outlet port and the liquid inlet port are respectively connected to a liquid storage apparatus through pipelines, and heat of the optical modules 5 is carried away through flowing of the cooling liquid in the internal flow channel, so that heat dissipation and cooling are realized.

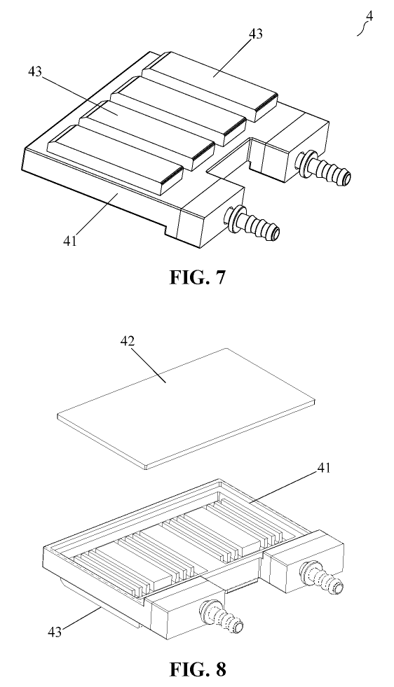

As shown in FIG. 7, the heat dissipator 4 further includes protrusions 43, and the protrusions 43 are arranged on the bottom surface of the liquid-cooling plate 41 in a protruding manner. A number, positions, and shapes of the protrusions 43 are consistent with those of the second heat dissipation holes 211. When the heat dissipator 4 is installed in the fastening structure, the protrusions 43 are out of the interiors of the corresponding second heat dissipation holes 211.

In some embodiments, the second heat dissipation holes 211 are rectangular through holes, and correspondingly, the protrusions 43 are rectangular solids. Moreover, dimensions of the second heat dissipation holes 211 are basically equivalent to those of the protrusions 43, and the second heat dissipation holes 211 are aligned with the protrusions 43. Therefore, after the protrusions 43 is out from the second heat dissipation holes 211, due to the equivalent dimensions, the protrusions 43 basically do not shake, so that a more stable structure is achieved. In some other alternative embodiments, the second heat dissipation holes 211 may be formed to be circular, polygonal, or irregularly-shaped through holes, and the protrusions 43 may also be arranged to be three-dimensional bodies with other shapes, which are not limited in the embodiments.

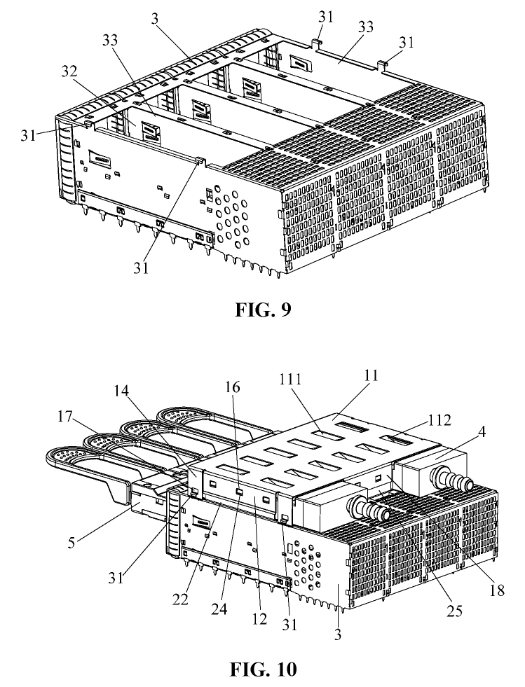

As shown in FIG. 9, two sides of the shielding cage 3 are provided with second snap-fitting parts 31, and the second snap-fitting parts 31 are connected to the second snap parts 17 of the fastening structure in a snap-fitting manner. The second snap-fitting parts 31 at two sides of the shielding cage 3 are consistent in number and corresponding in position with the second snap parts 17 on the third upper side plate 14 and the fourth upper side plate 15, so that firm installation and detachment are facilitated, and connection stability is improved. In some embodiments, the second snap parts 17 are snaping holes, and the second snap-fitting parts 31 are hanging lugs which extend upwards from two sides of the top surface of the shielding cage 3 and then bend towards the outside of the shielding cage 3. In addition, the second snap-fitting parts 31 may also be bumps which protrude towards the outside of the shielding cage 3. The snaping holes may be triangular, rectangular, polygonal, or circular, and the bumps may be triangular, rectangular, polygonal, or circular.

As shown in FIG. 9, the shielding cage 3 includes accommodating cavities 32, and the accommodating cavities 32 are used for installing optical modules 5. As shown in FIG. 9, third heat dissipation holes 33 are formed in the top surface of the shielding cage 3, and communicate with the accommodating cavities 32. The third heat dissipation holes 33 allow the protrusions 43 of the heat dissipator 4 to pass through and extend into the accommodating cavities 32, and then be direct contact with the optical modules 5 or approach the optical modules 5 at a closer distance, so that heat dissipation efficiency is increased to a certain extent.

In some embodiments, a plurality of the accommodating cavities 32 are formed in the shielding cage 3, and the plurality of the accommodating cavities 32 are arranged in a length direction, and one optical module 5 may be installed in a corresponding accommodating cavity 32, so that higher information interaction efficiency is achieved. Correspondingly, there are a plurality of third heat dissipation holes 33 which are in one-to-one correspondence with the plurality of accommodating cavities 32. Meanwhile, there are a plurality of second heat dissipation holes 211 in one-to-one correspondence with the plurality of third heat dissipation holes 33 and a plurality of protrusions 43 in one-to-one correspondence with the plurality of third heat dissipation holes 33. The plurality of protrusions 43 respectively extend into the corresponding third heat dissipation holes 33 and then extend into the corresponding accommodating cavities 32, and are in direct contact with the optical modules 5 or approach the optical modules 5 at a close distance, so that uniform heat dissipation for the plurality of optical modules 5, and high heat dissipation efficiency are achieved.

In some embodiments, the accommodating cavity 32 is of a rectangular hollow structure, the third heat dissipation holes 33 and the second heat dissipation holes 211 are rectangular through holes, and correspondingly, the protrusions 43 are rectangular solids. Moreover, dimensions of the third heat dissipation holes 33 and the second heat dissipation holes 211 are basically equivalent to those of the protrusions 43, and the third heat dissipation holes 33 and the second heat dissipation holes 211 are aligned with the protrusions 43. Therefore, after the protrusions 43 is out from the second heat dissipation holes 211 and the third heat dissipation holes 33, due to the equivalent dimensions, the protrusions 43 basically do not shake, so that a more stable structure is achieved. In some other alternative embodiments, the third heat dissipation holes 33 and the second heat dissipation holes 211 may be formed to be circular, polygonal, or irregularly-shaped through holes, and the protrusions 43 may be arranged to be three-dimensional bodies with other shapes, which are not limited in the present disclosure.

Embodiments of the present disclosure further provide an optical module apparatus, and the optical module apparatus includes a shielding cage assembly and optical modules 5. A structure of the shielding cage assembly has been described above and is not repeated herein. The optical modules 5 are arranged in accommodating cavities 32 of the shielding cage 3, and a number of the optical modules 5 is consistent with that of the accommodating cavities 32.

In embodiments of the present disclosure, the fastening structure is a structure wrapping around all outer sides of the heat dissipator, and after the fastening structure is connected to the shielding cage, good contact between the heat dissipator and heat sources (the optical modules) is guaranteed, thereby improving heat dissipation efficiency. The fastening structure formed through snap-fitting connection provides better mechanical support, and prevents the heat dissipator from displacement or loosening when external impact or vibration occurs, thereby improving stability and reliability of the heat dissipator. The design of the wrapping around all outer sides of the heat dissipator allows rapid adjustment according to different heat dissipation needs, and is applicable to many different devices and application scenes. Due to the snap-fitting design of the fastening structure and the snap-fitting connection with the shielding cage, installation or detachment is carried out without tools, so that an installation flow is simplified, time and cost are saved, and meanwhile, later maintenance or replacement is also facilitated.

The above descriptions are merely the preferred examples of the present disclosure, and are not intended to limit the present disclosure, and for those skilled in the art, various modifications and variations may be made to the present disclosure. Any modifications, equivalent substitutions, improvements, etc. made within the spirit and principle of the present disclosure shall fall within the protection scope of the present disclosure.

What is claimed is:

1. A fastening structure for a heat dissipator, comprising:
a first fastening member comprising a first rectangular box structure, the first rectangular box structure comprising an opening at a bottom, wherein each of four side surfaces of the first fastening member comprises a first snap part, each of two side surfaces arranged along a length direction of the first fastening member comprises a second snap part, and a top surface of the first fastening member comprises a plurality of elastic pressing sheets; and
a second fastening member comprising a second rectangular box structure, the second rectangular box structure comprising an opening at a top, wherein each of four side surfaces of the second fastening member comprises a first snap-fitting part;
wherein when the first fastening member and the second fastening member are fastened in an up-down direction, the first snap parts of the first fastening member and the first snap-fitting parts of the second fastening member are engaged in one-to-one correspondence, an accommodating space for placing the heat dissipator is formed between the first fastening member and the second fastening member, the second snap parts are configured to be connected to a shielding cage in a snap-fitting manner, and the elastic pressing sheets extend towards an interior of the accommodating space, and are configured to press the heat dissipator.

2. The fastening structure for the heat dissipator according to claim 1, wherein the first fastening member comprises a top plate, a first upper side plate, a second upper side plate, a fifth upper side plate, and a sixth upper side plate, the first upper side plate and the second upper side plate are located at two sides of the top plate in the length direction, the fifth upper side plate and the sixth upper side plate are located at two sides of the top plate in a width direction, and the first snap parts are arranged on the first upper side plate, the second upper side plate, the fifth upper side plate, and the sixth upper side plate;
the second fastening member comprises a bottom plate, a first lower side plate, a second lower side plate, a third lower side plate, and a fourth lower side plate, the first lower side plate and the second lower side plate are located at two sides of the bottom plate in the length direction, the third lower side plate and the fourth lower side plate are located at two sides of the bottom plate in a width direction, and the first snap-fitting parts are arranged on the first lower side plate, the second lower side plate, the third lower side plate, and the fourth lower side plate;
wherein the top plate is located over the bottom plate,
the first upper side plate and the first lower side plate are connected in a snap-fitting manner through the corresponding first snap parts and first snap-fitting parts, the second upper side plate and the second lower side plate are connected in a snap-fitting manner through the corresponding first snap parts and first snap-fitting parts, the fifth upper side plate and the third lower side plate are connected in a snap-fitting manner through the corresponding first snap parts and first snap-fitting parts, and the sixth upper side plate and the fourth lower side plate are connected in a snap-fitting manner through the corresponding first snap parts and first snap-fitting parts.

3. The fastening structure for the heat dissipator according to claim 2, wherein the first fastening member further comprises a third upper side plate and a fourth upper side plate which are located at the two sides of the top plate in the length direction, the first upper side plate and the third upper side plate are positioned at the same side of the top plate and arranged in the width direction, the second upper side plate and the fourth upper side plate are positioned at the same side of the top plate and arranged in the width direction, and the second snap parts are arranged on the third upper side plate and the fourth upper side plate.

4. The fastening structure for the heat dissipator according to claim 3, wherein the third upper side plate comprises a plurality of third upper side plates, and the plurality of third upper side plates are arranged at intervals through the first upper side plate, and the fourth upper side plate comprises a plurality of fourth upper side plates, and the plurality of fourth upper side plates are arranged at intervals through the second upper side plate.

5. The fastening structure for the heat dissipator according to claim 1, wherein the first snap parts and the second snap parts are snaping holes, and the first snap-fitting parts are bumps protruding outwardly.

6. The fastening structure for the heat dissipator according to claim 3, wherein each of the first upper side plate, the second upper side plate, the third upper side plate, and the fourth upper side plate is provided with a guide plate extending in a direction away from the top plate, and the guide plate is inclined outwardly.

7. The fastening structure for the heat dissipator according to claim 2, wherein a plurality of first heat dissipation holes are formed in the top plate, and each of the elastic pressing sheets is arranged at one side of a corresponding one of the first heat dissipation holes.

8. The fastening structure for the heat dissipator according to claim 7, wherein the first heat dissipation holes are rectangular holes, and the plurality of first heat dissipation holes and the plurality of elastic pressuring sheets are arranged in a matrix.

9. The fastening structure for the heat dissipator according to claim 2, wherein the bottom plate is provided with second heat dissipation holes which allow the heat dissipator to extend out.

10. The fastening structure for the heat dissipator according to claim 2, wherein the bottom plate is further provided with avoidance holes.

11. A shielding cage assembly, comprising: a fastening structure, a shielding cage, and a heat dissipator,
wherein the fastening structure comprises: a first fastening member and a second fastening member,
the first fastening member comprises a first rectangular box structure, the first rectangular box structure comprises an opening at a bottom, each of four side surfaces of the first fastening member comprises a first snap part, each of two side surfaces arranged along a length direction of the first fastening member comprises a second snap part, and a top surface of the first fastening member comprises a plurality of elastic pressing sheets;
the second fastening member comprises a second rectangular box structure, he second rectangular box structure comprising an opening at a top, and each of four side surfaces of the second fastening member comprises a first snap-fitting part;
when the first fastening member and the second fastening member are fastened in an up-down direction, the first snap parts of the first fastening member and the first snap-fitting parts of the second fastening member are engaged in one-to-one correspondence, an accommodating space for placing the heat dissipator is formed between the first fastening member and the second fastening member, the second snap parts are configured to be connected to a shielding cage in a snap-fitting manner, and the elastic pressing sheets extend towards an interior of the accommodating space, and are configured to press the heat dissipator;
two sides of the shielding cage are provided with second snap-fitting parts which are configured to be connected to the second snap parts of the fastening structure in a snap-fitting manner, and the fastening structure is disposed above and fastened to the shielding cage in a snap-fitting manner; and
the heat dissipator is located in the accommodating space of the fastening structure.

12. The shielding cage assembly according to claim 11, wherein the second snap-fitting parts are hanging lugs which extend upwards from two sides of the top surface of the shielding cage and then bend away from the shielding cage.

13. The shielding cage assembly according to claim 11, wherein a plurality of accommodating cavities are formed in the shielding cage, the plurality of accommodating cavities are arranged in parallel along a length direction of the shielding cage, and each of the accommodating cavities is configured to install an optical module;
a plurality of third heat dissipation holes are formed in the top surface of the shielding cage, the plurality of third heat dissipation holes are arranged in parallel along the length direction, a plurality of second heat dissipation holes are formed in the bottom plate of the fastening structure, the plurality of second heat dissipation holes are arranged in parallel along the length direction, the plurality of second heat dissipation holes are arranged in one-to-one correspondence with the plurality of accommodating cavities and communicated with the corresponding accommodating cavities, and the plurality of third heat dissipation holes are arranged in one-to-one correspondence with the plurality of accommodating cavities and communicated with the corresponding accommodating cavities; and
the bottom surface of the heat dissipator is provided with a plurality of protrusions arranged in parallel, and the plurality of protrusions extend into the corresponding accommodating cavities via the corresponding second heat dissipation holes and third heat dissipation holes.

14. The shielding cage assembly according to claim 11, wherein the heat dissipator comprises a liquid-cooling plate, a pressing flat plate, and protrusions located on a bottom surface of the liquid-cooling plate, the pressing flat plate is arranged on a top surface of the liquid-cooling plate, and the elastic pressing sheets of the fastening structure are abutted against the pressing flat plate.

15. An optical module apparatus, comprising:
a shielding cage assembly; and
optical modules,
wherein the shielding cage assembly comprises: a fastening structure, a shielding cage, and a heat dissipator,
the fastening structure comprises: a first fastening member and a second fastening member,
the first fastening member has a first rectangular box structure, the first rectangular box structure comprises an opening at a bottom, each of four side surfaces of the first fastening member comprises a first snap part, each of two side surfaces of the first fastening member comprises a second snap part, and a top surface of the first fastening member comprises a plurality of elastic pressing sheets;
the second fastening member has a second rectangular box structure, the second rectangular box structure comprises an opening at a top, and each of four side surfaces of the second fastening member comprises a first snap-fitting part;
when the first fastening member and the second fastening member are fastened in an up-down direction, the first snap parts of the first fastening member and the first snap-fitting parts of the second fastening member are engaged in one-to-one correspondence, an accommodating space for placing the heat dissipator is formed between the first fastening member and the second fastening member, the second snap parts are configured to be connected to a shielding cage in a snap-fitting manner, and the elastic pressing sheets extend towards an interior of the accommodating space, and are configured to press the heat dissipator;
two sides of the shielding cage are provided with second snap-fitting parts which are configured to be connected to the second snap parts of the fastening structure in a snap-fitting manner, and the fastening structure is disposed above and fastened to the shielding cage in a snap-fitting manner;
the heat dissipator is located in the accommodating space of the fastening structure; and the optical modules are arranged in the shielding cage.

16. The optical module apparatus according to claim 15, wherein the second snap-fitting parts are hanging lugs which extend upwards from two sides of the top surface of the shielding cage and then bend away from the shielding cage.

17. The optical module apparatus according to claim 15, wherein a plurality of accommodating cavities are formed in the shielding cage, the plurality of accommodating cavities are arranged in parallel along a length direction of the shielding cage, and each of the accommodating cavities is configured to install the optical module;
a plurality of third heat dissipation holes are formed in the top surface of the shielding cage, the plurality of third heat dissipation holes are arranged in parallel along the length direction, a plurality of second heat dissipation holes are formed in the bottom plate of the fastening structure, the plurality of second heat dissipation holes are arranged in parallel along the length direction, the plurality of second heat dissipation holes are arranged in one-to-one correspondence with the plurality of accommodating cavities and communicated with the corresponding accommodating cavities, and the plurality of third heat dissipation holes are arranged in one-to-one correspondence with the plurality of accommodating cavities and communicated with the corresponding accommodating cavities; and
the bottom surface of the heat dissipator comprises a plurality of protrusions arranged in parallel, and the plurality of protrusions extend into the corresponding accommodating cavities via the corresponding second heat dissipation holes and third heat dissipation holes.

18. The optical module apparatus according to claim 15, wherein the heat dissipator comprises a liquid-cooling plate, a pressing flat plate, and protrusions located on a bottom surface of the liquid-cooling plate, the pressing flat plate is arranged on a top surface of the liquid-cooling plate, and the elastic pressing sheets of the fastening structure are abutted against the pressing flat plate.

19. The optical module apparatus according to claim 15, wherein the first fastening member comprises a top plate, a first upper side plate, a second upper side plate, a fifth upper side plate, and a sixth upper side plate, the first upper side plate and the second upper side plate are located at two sides of the top plate in the length direction, the fifth upper side plate and the sixth upper side plate are located at two sides of the top plate in a width direction, and the first snap parts are arranged on the first upper side plate, the second upper side plate, the fifth upper side plate, and the sixth upper side plate;
the second fastening member comprises a bottom plate, a first lower side plate, a second lower side plate, a third lower side plate, and a fourth lower side plate, the first lower side plate and the second lower side plate are located at two sides of the bottom plate in the length direction, the third lower side plate and the fourth lower side plate are located at two sides of the bottom plate in a width direction, and the first snap-fitting parts are arranged on the first lower side plate, the second lower side plate, the third lower side plate, and the fourth lower side plate;
wherein the top plate is located over the bottom plate,
the first upper side plate and the first lower side plate are connected in a snap-fitting manner through the corresponding first snap parts and first snap-fitting parts, the second upper side plate and the second lower side plate are connected in a snap-fitting manner through the corresponding first snap parts and first snap-fitting parts, the fifth upper side plate and the third lower side plate are connected in a snap-fitting manner through the corresponding first snap parts and first snap-fitting parts, and the sixth upper side plate and the fourth lower side plate are connected in a snap-fitting manner through the corresponding first snap parts and first snap-fitting parts.

20. The optical module apparatus according to claim 19, wherein the first fastening member further comprises a third upper side plate and a fourth upper side plate which are located at the two sides of the top plate in the length direction, the first upper side plate and the third upper side plate are positioned at the same side of the top plate and arranged in the width direction, the second upper side plate and the fourth upper side plate are positioned at the same side of the top plate and arranged in the width direction, and the second snap parts are arranged on the third upper side plate and the fourth upper side plate.
